(19) United States
(12) Patent Application Publication
(10) Pub. No.: US 2004/0192059 A1
(43) Pub. Date: Sep. 30, 2004

(54) Method for etching a titanium-containing layer prior to etching an aluminum layer in a metal stack

(75) Inventors: Woody K. Sattayapiwat Tang, Saratoga, CA (US); George A. Kovall, Campbell, CA (US)

Correspondence Address: BEVER HOFFMAN & HARMS, LLP, TRI-VALLEY OFFICE, 1432 CONCANNON BLVD., BLDG. G, LIVERMORE, CA, 94550, US

(73) Assignee: Mosel Vitelic, Inc.

(21) Appl. No.: 10/402,745

(22) Filed: Mar. 28, 2003

(51) Int. Cl. H01L 21/302; H01L 21/461

(52) U.S. Cl. 438/710

(57) ABSTRACT

A method of plasma etching a metal stack on a semiconductor wafer is presented. The metal stack includes an aluminum layer overlaid with a titanium-containing anti-reflective coating (ARC) layer. The method includes flowing a fluorine-containing species (e.g., SF₆) and a chlorine-containing species (e.g., BCl₃ and Cl₂) into a plasma etch chamber while etching the titanium-containing ARC layer.

### BACKGROUND OF THE INVENTION

a. Field of the Invention

The present invention relates to the fabrication of integrated circuits. More particularly, the invention relates to the etching of a metal interconnect layer during the making of an integrated circuit.

b. Description of the Related Art

In the course of making integrated circuits, layers of semiconductor material, metals, and dielectrics are selectively deposited and removed from a semiconductor substrate. One step in making such integrated circuits involves etching metal layers into interconnect structures. Such a process is depicted in FIGS. 1 and 2. These figures are not drawn to scale.

Referring to FIG. 1, a semiconductor substrate 10 includes metal stack 14 over which a patterned photoresist mask 12 has been formed by photolithography. Mask 12 includes features such as lines 13, which have a width and a pitch. The object of the process is to transfer the pattern of the photoresist mask 12 into the metal stack 14.

In particular, semiconductor substrate 10 includes a dielectric layer 16 (e.g., oxide) over which metal stack 14 is formed. Metal stack 14 includes several successive layers of different types of metal, in ascending order, a titanium layer 18, a bulk aluminum layer 20, and an inorganic anti-reflective coating (ARC) layer 22. Anti-reflective coating layer 22 is a bilayer including a titanium layer 24 and a titanium nitride (TiN) layer 26. Typical thicknesses of the layers of metal stack 14 include: titanium layer 18 at about 100-150 Angstroms; aluminum layer 20 at about 2,500 to 3,000 Angstroms, titanium layer 24 at about 60 to 100 Angstroms, and TiN layer 26 at about 350 to 400 Angstroms. “Aluminum” as used herein includes pure aluminum and aluminum alloys, such as aluminum copper alloy. Of course, these thicknesses may vary.

Photoresist mask 12 is formed of a polymeric material that includes a photoactive compound. Between photoresist mask 12 and TiN layer 26 is an unpatterned layer of an organic bottom anti-reflective coating (BARC) layer 28. BARC layer 28 is formed of the same polymeric material as photoresist mask 12, but lacks the photoactive compound that allows photoresist mask 12 to be patterned by photolithography. Photoresist mask 12 may have a thickness of about 6,000 Angstroms, and organic BARC layer 28 may have a thickness of about 800 Angstroms. Of course, these thicknesses may vary.

Table 1 sets forth a conventional process for etching through organic BARC layer 28 and metal stack 14. The process has five steps: (1) etch of organic BARC layer 28; (2) etch of inorganic ARC layer 22, with endpoint detection; (3) main aluminum etch, with endpoint detection; (4) first overetch; and (5) second overetch. The process is entirely performed in a TCP 9600 inductively coupled, high density plasma etcher from Lam Research Corporation of Fremont, Calif. Two out of several electrical process parameters for the Lam TCP 9600 are the amount of radio-frequency (RF) power provided to the tool's induction coil (denoted as transformer coupled power, “TCP”) and the amount of RF power applied to the tool's bottom electrode (“BE”). A typical RF power source would operate at a frequency of 13.56 MHz. Note that, in the conventional process, at least one chlorine-containing gas, either Cl₂ or a combination of Cl₂ and BCl₃, are used in each of the five steps.

TABLE 1

| | Total | | | | | | |
|---|---|---|---|---|---|---|---|
| | pressure | TCP | BE | Cl₂ | BCl₃ | Ar | N₂ |
| Step | (mTorr) | (Watts) | (Watts) | (sccm) | (sccm) | (sccm) | (sccm) |
| 1 | 15 | 600 | 100 | 50 | — | 50 | 6 |
| 2 | 10 | 250 | 230 | 50 | 40 | — | 6 |
| 3 | 10 | 250 | 230 | 50 | 40 | — | 6 |
| 4 | 10 | 250 | 270 | 40 | 60 | — | 10 |
| 5 | 10 | 400 | 200 | 30 | 50 | 30 | — |

As mentioned above, an endpoint detection system is used to indicate imminent completion of the aluminum etch step. Subsequently, two overetch steps are performed to complete etch through of aluminum layer 20, and to etch through titanium layer 18. The overetch steps are designed so that all stringers and metallic residues are cleared between the metal lines that are etched. If such stringers and residues are not completely removed, then adjacent lines inadvertently may be electrically connected, i.e., shorted, together. To avoid such problems, the overetch steps typically entail etching some distance, e.g., 500 Angstroms, into the underlying dielectric layer 16.

FIG. 2 shows an end result of the etch step. The features of photoresist mask 12 are transferred into metal stack 14 of FIG. 1, thereby forming metal lines 30. Note that the etching was highly anisotropic, proceeding more in a vertical direction than in a lateral direction. This result is obtained due to the directional nature of the plasma in the etch chamber, and to the formation of a thin layer of a protective polymer (not shown) on the sidewalls 32 of the nascent features during the etch process. The polymer protects the metal of the nascent sidewalls 32 from the corrosive plasma environment. The protective sidewall polymer originates, primarily, from the photoresist mask 12, which erodes during the etch process, and from residues in the etch chamber.

However, as the layer of protective polymer accumulates on the nascent sidewalls 32 of the various layers of metal stack 14, the layer of protective polymer extends laterally. Accordingly, the layer of protective polymer has a masking effect in the vertical direction. As a result, the metal lines 30 are slightly, and undesirably, wider than the photoresist lines 13 of photoresist mask 12. The width of the lines 30 is greatest at the bottom of the etched metal stack, because the thickness of the protective polymer layer on the nascent sidewalls 32 increases through the etch process. That is, the vertical masking due to the polymer layer on the sidewalls is greatest toward the end of the process. Accordingly, the sidewalls 32 have a slope, indicated by angle θ, that can be far less than 90 degrees.

The mismatch between the width of the photoresist lines 13 and the metal lines 30 is becoming increasingly problematic, because of a trend in the industry to continually shrink the size of integrated circuit features, so that smaller and higher packing density of the integrated circuits can be built.

One way to shrink the width of metal lines 30 is to form narrower features in the photoresist mask 12. There is further capability to form narrower lines using the current generation of lithography equipment. The current generation lithography equipment uses ultraviolet light having a wavelength of about 248 nm. However, because of the inability of current etch processes to closely match the metal line width to the photoresist line without a complex and costly modification of the photomask, it would be less costly to obtain a narrower metal line width by improving the etch process.

Another possibility is to upgrade one's lithography equipment. The newest lithography equipment on the market uses deep ultraviolet light having a wavelength of 193 nm. Generally, the smaller the wavelength of light used to expose the photoresist, the smaller the size of the features, e.g., lines 13, that can be formed in the photoresist mask 12. With smaller width lines 13 formed in photoresist mask 12, smaller width lines could be transferred into metal stack 14.

Changing lithography equipment, however, would be a major endeavor for a semiconductor fabrication facility, for several reasons. First, the cost of the new generation lithography equipment is significant, e.g., $15 million per unit. Second, the new generation lithography equipment requires a new generation of photoresist material, developer chemicals, developing equipment, and the like, which are more costly than what is now used with the current generation lithography equipment. Third, even if the equipment cost was incurred, then a whole host of procedures for using the new equipment would have to be developed and tested, which also would entail a significant cost in time and money.

In view of these obstacles, it would be better to improve the etch process to obtain narrower metal lines 30, at a smaller pitch, so that the life of the current generation (i.e., 248 nm) lithography tools can be extended.

### SUMMARY

In accordance with the present invention, a method for reducing the size of features formed during the etching of an aluminum-containing metal stack metal stack is presented.

In accordance with one embodiment of the present invention, at least one fluorine-containing gas is provided to the plasma environment during the etching of a titanium-containing inorganic ARC layer that overlies a bulk aluminum layer. The addition of the fluorine-containing gas to the usual chlorine-containing gas (or gases) normally used for etching through the inorganic ARC layer results in greater lateral etching of the inorganic ARC layer. With the width of the nascent metal line in the ARC layer reduced, there is less vertical masking as the bulk aluminum layer begins etching. Accordingly, the width of the metal line at the end of the etch process is reduced. The width and shape of the etched metal line, therefore, more closely match the width and shape of the transferred feature of the photoresist mask. With such excellent performance in the etch process, the life of the current generation of lithography tools can be extended.

These and other aspects of the present invention will be illustrated further by the following detailed description.

### BRIEF DESCRIPTION OF THE DRAWINGS

FIG. 1 is a cross-sectional side view of a photoresist mask overlying an aluminum-containing metal stack on a semiconductor wafer.

FIG. 2 is a cross-sectional side view of the metal stack of FIG. 1 after etching, and after removal of the residual photoresist mask.

In the drawings, like features in the various drawings have the same reference numbers.

### DETAILED DESCRIPTION

Our addition of a fluorine-containing species to the chlorine-containing species normally used for plasma etching the titanium-containing inorganic ARC layer overlying an aluminum metal stack achieves a more close matching between the width of the photoresist feature and the width of the metal feature formed at the completion of the etch process. In addition, the slope of the sidewall of the etched metal feature is increased. Accordingly, metal lines having essentially vertical sidewalls, for example, with sidewall angles (angle θ in FIG. 2) of 89+/−1 degree, at line line:space ratios of 1:1 or better, can be formed in a consistent manner. Such outstanding etch process performance will allow practitioners to have an option to extend the life of the current generation of lithography equipment.

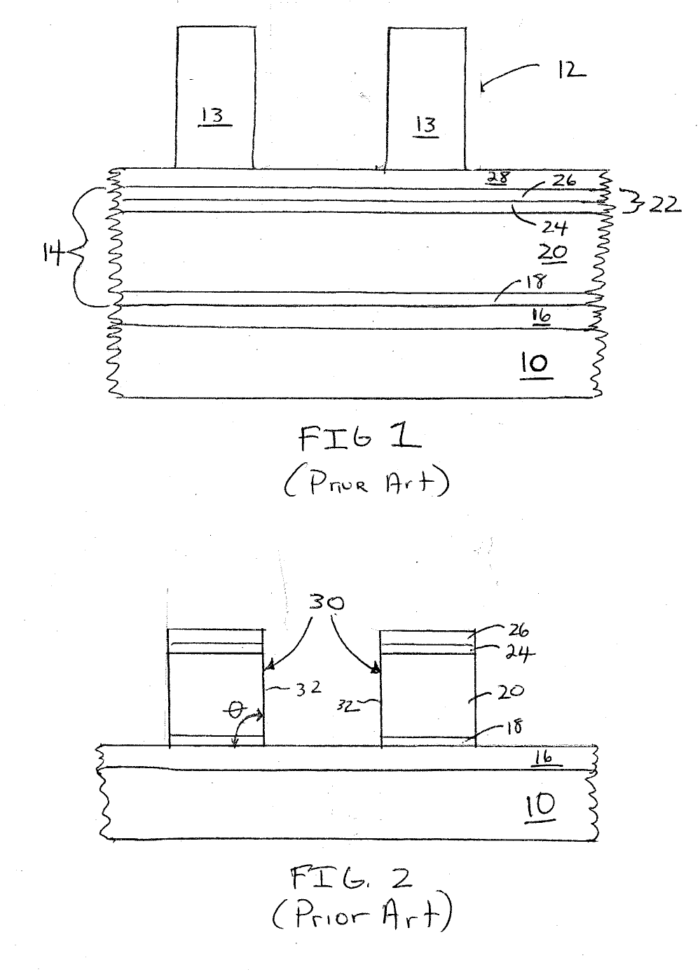

The metal stack 14 shown in FIG. 1 may be etched using our process. As mentioned, metal stack 14 includes an inorganic ARC layer. 22 consisting of two titanium-containing metal layers, namely, a topmost TiN layer 26 under organic BARC layer 28, and a lowermost titanium layer 24 on aluminum layer 20. However, our process is not limited to such an inorganic ARC layer. Generally speaking, our invention would apply to any variation of titanium-containing layers over aluminum layer 20. For instance, in addition to the TiN/Ti configuration of FIG. 1, ARC layer 22 could consist of a single layer of titanium, a single layer of TiN, or Ti/TiN bilayer, among other possibilities.

In our process, after the etching through of organic BARC layer 28 in the conventional manner set forth in Table 1 above, a fluorine-containing gas is flowed into the plasma etch reactor, e.g., the TCP 9600, along with the usual chlorine-based etch gases (Cl₂ and BCl₃) during the etch through of inorganic ARC layer 22. The particular fluorine-containing gas used can vary. For instance, CF₄, CHF₃, NF₃, or SF₆, or some combination of these gases, can be used. In an exemplary embodiment discussed below, SF₆ is used as the fluorine-containing species.

Table 2 below shows a range of possible process parameters, and one specific example process, for etching the titanium-containing inorganic ARC layer 22 of metal stack 14. The etch reactor is the Lam TCP 9600 etch chamber. A gas mixture of BCl₃/Cl₂/SF₆ is flowed into the plasma etch chamber during the plasma etching of both TiN layer 26 and titanium layer 24 of ARC layer 22.

TABLE 2

| | | | | | Total | |
|---|---|---|---|---|---|---|
| | | | | | flow | |
| | Total | | | | (sccm) | |
| | pressure | TCP | BE | SF₆ | (BCl₃/Cl₂/ | |
| | (mTorr) | (Watts) | (Watts) | (sccm) | SF₆) | Time |
| Range | 7-15 | 350-800 | 80-200 | 10-40 | 80-110 | endpoint |
| Ex- | 15 | 600 | 140 | 40 | 30/40/40 | endpoint |
| ample | | | | | | |

After the etching of ARC layer 22 is completed, then the flow of the fluorine-containing gas may be ceased. The remainder of the metal stack 14, including aluminum layer 20 and titanium layer 18, may be etched in the conventional manner provided in Table 1.

It is believed that the addition of the fluorine-containing species to the usual Cl2 and BCl3 gases used for etching through ARC layer 22 causes a greater amount of lateral etching of the ARC layer 22 than the usual process. This could be due to the etchant mixture having a greater lateral etch than the conventional mixture, or a lesser production of the protective sidewall polymer, or both.

With a reduction in the line width of the etched ARC layer 22, the sidewall polymer is inward of its usual location. Accordingly, the subsequent etching of the underlying aluminum layer 20 begins inward of its usual location, and this advantage is compounded through the remainder of the etch process. The result is a steeper metal line 30 that more-closely matches the width of the mask line 14 than what was achieved in the prior art.

The invention is not limited to the exemplary embodiments described above. Other embodiments and variations are within the scope of the invention, as defined by the appended claims. In addition, although various aspects and features of the present invention have been explained or described in relation to beliefs or theories, it should be understood that the invention is not bound to any particular belief or theory.

1. A method for etching an aluminum stack on a wafer, comprising:
providing a wafer in an etch chamber, said wafer comprising an aluminum layer over which a titanium-containing inorganic anti-reflective coating (ARC) layer and a photoresist mask are disposed;
etching the inorganic ARC layer according to a pattern in the photoresist layer in a plasma-environment in the etch chamber while flowing a fluorine-containing gas into the etch chamber; and
etching the aluminum layer according to the pattern in the photoresist layer in a plasma-environment in the etch chamber while flowing at least one chlorine-containing gas into the etch chamber.

2. The method of claim 1, wherein the fluorine-containing gas is at least one of CF₄, CHF₃, NF₃ and SF₆.

3. The method of claim 1, wherein the inorganic ARC layer comprises a sublayer of titanium and a sublayer of titanium nitride.

4. The method of claim 1, wherein the at least one chorine-containing gas comprises Cl₂ and BCl₃, and the Cl₂ and BCl₃ also are flowed into the etch chamber during the etching of the inorganic ARC layer.

5. The method of claim 4, wherein a volumetric percentage of the fluorine-containing gas in a total gas flow during the etching of the inorganic ARC layer is about 10% to about 40% of the total gas flow.

6. The method of claim 1, wherein a volumetric percentage of the fluorine-containing gas in a total gas flow during the etching of the inorganic ARC layer is about 10% to about 40% of the total gas flow.

7. The method of claim 6, wherein the volumetric percentage of the fluorine-containing gas in the total gas flow during the etching of the inorganic ARC layer is 30% to 40% of the total gas flow.

8. The method of claim 1, wherein an organic bottom antireflective coating (BARC) layer is between the photoresist mask and the titanium-containing inorganic ARC layer, and further comprising etching the organic BARC layer according to a pattern in the photoresist layer in a plasma-environment in the etch chamber prior to the etching of the inorganic ARC layer.

9. A method of etching metal stack on a wafer, comprising:
providing a wafer comprising a titanium-containing layer on an aluminum layer, with an overlying patterned photoresist mask, in a plasma etch chamber;
etching the titanium-containing layer through the photoresist mask in a plasma environment in the etch chamber while flowing at least one fluorine-containing gas and at least one chlorine-containing gas into the etch chamber;
etching the aluminum layer through the photoresist mask in a plasma environment in the etch chamber while flowing the at least one chlorine-containing gas into the etch chamber.

10. The method of claim 9, wherein the fluorine-containing gas is at least one of CF₄, CHF₃, NF₃, and SF₆.

11. The method of claim 10, wherein the at least one chlorine-containing gas includes both BCl₃ and Cl₂.

12. The method of claim 11, wherein a flow ratio of the fluorine-containing gas to the at least one chlorine-containing gas during the etching of the titanium-containing layer is about 10% to about 40% of a total gas flow.
